(19) United States
(12) Patent Application Publication
(10) Pub. No.: US 2026/0282529 A1
(43) Pub. Date: Sep. 17, 2026

(54) VERTICAL METAL LINERS FOR GATE MERGE IN SEQUENTIAL FETS

(71) Applicant: International Business Machines Corporation, Armonk, NY (US)

(72) Inventors: Eunsoo Cho, Albany, NY (US); Shay Reboh, Guilderland, NY (US); Thanh Nguyen, Troy, NY (US); Ruilong Xie, Niskayuna, NY (US); Utkarsh Bajpai, Suffern, NY (US); James Patrick Mazza, Saratoga Springs, NY (US)

(21) Appl. No.: 19/079,929

(22) Filed: Mar. 14, 2025

(51) Int. Cl. H10D 84/83; H10D 64/27; H10D 84/01

(52) U.S. Cl. CPC H10D 84/8316; H10D 64/518; H10D 84/0135; H10D 84/0153; H10D 84/832

(57) ABSTRACT

A stacked field effect transistor (FET) device is provided and includes a lower FET, an upper FET disposed over the lower FET in a vertically mis-aligned formation, oxide vertically interposed between the lower FET and the upper FET and a gate merge connection. The lower FET includes lower gate metal surrounding semiconductor channels and a self-aligned contact (SAC) cap disposed over the lower gate metal. The upper FET includes upper gate metal surrounding semiconductor channels. The gate merge connection includes a metal plug disposed in the SAC cap and in contact with the lower gate metal and a metal liner disposed as a spacer along the upper gate metal and the oxide and in contact with the metal plug.

### BACKGROUND

The present disclosure generally relates to fabrication methods and resulting structures for semiconductor devices. More specifically, the present disclosure relates to vertical metal liners for gate merge in sequential field effect transistors (FETs).

A transistor is a semiconductor device used to amplify or switch electrical signals and power and is one of the basic building blocks of modern electronics. An FET is a type of transistor that uses an electric field to control the flow of current in a semiconductor. An FET has three terminals: a source, a gate and a drain. FETs control the flow of current by the application of a voltage to the gate, which in turn alters the conductivity between the drain and the source.

### SUMMARY

According to an aspect of the present invention, a stacked field effect transistor (FET) device is provided and includes a lower FET, an upper FET disposed over the lower FET in a vertically mis-aligned formation, oxide vertically interposed between the lower FET and the upper FET and a gate merge connection. The lower FET includes lower gate metal surrounding semiconductor channels and a self-aligned contact (SAC) cap disposed over the lower gate metal. The upper FET includes upper gate metal surrounding semiconductor channels. The gate merge connection includes a metal plug disposed in the SAC cap and in contact with the lower gate metal and a metal liner disposed as a spacer along the upper gate metal and the oxide and in contact with the metal plug. The stacked FET device thus provides for connection between respective gate metals of each of the upper FET device and the lower FET device.

According to an aspect of the present invention, a stacked field effect transistor (FET) device is provided and includes a lower FET, an upper FET disposed over the lower FET in a vertically mis-aligned formation, oxide vertically interposed between the lower FET and the upper FET and a gate merge connection. The lower FET includes lower gate metal surrounding semiconductor channels and a self-aligned contact (SAC) cap disposed over the lower gate metal. The upper FET includes upper gate metal surrounding semiconductor channels. The gate merge connection includes a metal plug disposed in the SAC cap in contact with the lower gate metal and a conformal metal liner disposed as a liner along the upper gate metal, the oxide, and the SAC cap and in contact with the metal plug. The stacked FET device thus provides for connection between respective gate metals of each of the upper FET device and the lower FET device.

According to an aspect of the present invention, a stacked field effect transistor (FET) device fabrication method is provided and includes forming a lower FET including lower gate metal surrounding semiconductor channels and a self-aligned contact (SAC) cap disposed over the lower gate metal, disposing a metal plug in the SAC cap and in contact with the lower gate metal, disposing oxide over the lower FET, the SAC cap, and the metal plug, forming, over the oxide in a vertically misaligned formation with the lower FET, an upper FET including upper gate metal surrounding semiconductor channels, executing gate cut patterning to expose the SAC cap and the metal plug and forming a metal liner along the upper gate metal and the oxide and in contact with the metal plug. The stacked FET device fabrication method thus provides for connection between respective gate metals of each of the upper FET device and the lower FET device.

Additional technical features and benefits are realized through the techniques of the present disclosure. Embodiments and aspects of the disclosure are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the disclosure are apparent from the following detailed description taken in conjunction with the accompanying drawings in which:

FIG. 1 is a side schematic view of a stacked FET device with a merge connection including a metal liner as a spacer in accordance with one or more embodiments of the present invention;

FIG. 2 is a side schematic view of a stacked FET device with a merge connection including a conformal metal liner as a liner in accordance with one or more embodiments of the present invention;

FIG. 3 is a flow diagram illustrating a stacked FET fabrication method in accordance with one or more embodiments of the present invention; and

FIG. 4 depicts side schematic views graphically illustrating the method of FIG. 3 in accordance with one or more embodiments of the present invention.

The diagrams depicted herein are illustrative. There can be many variations to the diagram or the operations described therein without departing from the spirit of the disclosure. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with two or three digit reference numbers. With minor exceptions, the leftmost digit(s) of each reference number correspond to the figure in which its element is first illustrated.

### DETAILED DESCRIPTION

According to an aspect of the present invention, a stacked field effect transistor (FET) device is provided and includes a lower FET, an upper FET disposed over the lower FET in a vertically mis-aligned formation, oxide vertically interposed between the lower FET and the upper FET and a gate merge connection. The lower FET includes lower gate metal surrounding semiconductor channels and a self-aligned contact (SAC) cap disposed over the lower gate metal. The upper FET includes upper gate metal surrounding semiconductor channels. The gate merge connection includes a metal plug disposed in the SAC cap and in contact with the lower gate metal and a metal liner disposed as a spacer along the upper gate metal and the oxide and in contact with the metal plug. The stacked FET device thus provides for connection between respective gate metals of each of the upper FET device and the lower FET device.

In accordance with one or more additional and/or alternative embodiments of the present invention, the oxide includes bonding oxide in order to insulate the lower FET from the upper FET.

In accordance with one or more additional and/or alternative embodiments of the present invention, the semiconductor channels are nanosheets which provide for an efficient FET structure.

In accordance with one or more additional and/or alternative embodiments of the present invention, the metal liner is disposed along respective sidewalls of the upper gate metal and the oxide to insulate the upper gate metal.

In accordance with one or more additional and/or alternative embodiments of the present invention, the metal plug is disposed between first and second sides of the SAC cap to make reliable contact with the lower gate metal.

In accordance with one or more additional and/or alternative embodiments of the present invention, the metal plug is vertically aligned with the metal liner to form a reliable electrical connection between the lower gate metal, the metal plug, the metal liner and the upper gate metal.

In accordance with one or more additional and/or alternative embodiments of the present invention, the metal plug is edge-wise vertically aligned with an edge of the upper FET to ensure reliable electrical contact.

In accordance with one or more additional and/or alternative embodiments of the present invention, the stacked FET device further includes filler material disposed on an uppermost surface of the SAC cap and along a sidewall of the metal liner to insulate the metal liner.

According to an aspect of the present invention, a stacked field effect transistor (FET) device is provided and includes a lower FET, an upper FET disposed over the lower FET in a vertically mis-aligned formation, oxide vertically interposed between the lower FET and the upper FET and a gate merge connection. The lower FET includes lower gate metal surrounding semiconductor channels and a self-aligned contact (SAC) cap disposed over the lower gate metal. The upper FET includes upper gate metal surrounding semiconductor channels. The gate merge connection includes a metal plug disposed in the SAC cap in contact with the lower gate metal and a conformal metal liner disposed as a liner along the upper gate metal, the oxide, and the SAC cap and in contact with the metal plug. The stacked FET device thus provides for connection between respective gate metals of each of the upper FET device and the lower FET device.

In accordance with one or more additional and/or alternative embodiments of the present invention, the oxide includes bonding oxide in order to insulate the lower FET from the upper FET.

In accordance with one or more additional and/or alternative embodiments of the present invention, the semiconductor channels are nanosheets which provide for an efficient FET structure.

In accordance with one or more additional and/or alternative embodiments of the present invention, the conformal metal liner is disposed along respective sidewalls of the upper gate metal and the oxide and is disposed along an uppermost surface of the SAC cap to insulate the conformal metal liner.

In accordance with one or more additional and/or alternative embodiments of the present invention, the metal plug is disposed between first and second sides of the SAC cap to make reliable contact with the lower gate metal.

In accordance with one or more additional and/or alternative embodiments of the present invention, the conformal metal liner includes a vertical section disposed along respective sidewalls of the upper gate metal and the oxide and a horizontal section disposed along an uppermost surface of the SAC cap and the metal plug is vertically aligned with the vertical section of the conformal metal liner to form a reliable electrical connection between the lower gate metal, the metal plug, the conformal metal liner and the upper gate metal.

In accordance with one or more additional and/or alternative embodiments of the present invention, the metal plug is edge-wise vertically aligned with an edge of the upper FET to ensure reliable electrical contact.

In accordance with one or more additional and/or alternative embodiments of the present invention, the stacked FET device further includes filler material disposed in a space bounded by the conformal metal liner to insulate the conformal metal liner.

According to an aspect of the present invention, a stacked field effect transistor (FET) device fabrication method is provided and includes forming a lower FET including lower gate metal surrounding semiconductor channels and a self-aligned contact (SAC) cap disposed over the lower gate metal, disposing a metal plug in the SAC cap and in contact with the lower gate metal, disposing oxide over the lower FET, the SAC cap, and the metal plug, forming, over the oxide in a vertically misaligned formation with the lower FET, an upper FET including upper gate metal surrounding semiconductor channels, executing gate cut patterning to expose the SAC cap and the metal plug and forming a metal liner along the upper gate metal and the oxide and in contact with the metal plug. The stacked FET device fabrication method thus provides for connection between respective gate metals of each of the upper FET device and the lower FET device.

In accordance with one or more additional and/or alternative embodiments of the present invention, the disposing of the metal plug includes edge-wise vertically aligning the metal plug with an edge of the upper FET to ensure reliable electrical contact.

In accordance with one or more additional and/or alternative embodiments of the present invention, the forming of the metal liner includes conformal metal deposition following the gate cut patterning and directional etching to expose the SAC cap and to form the metal liner as a spacer and the stacked FET device fabrication method further includes a fill operation following the directional etching on an uppermost surface of the SAC cap and along a sidewall of the metal liner to insulate the metal liner.

In accordance with one or more additional and/or alternative embodiments of the present invention, the forming of the metal liner includes conformal metal liner deposition following the gate cut patterning to form a conformal metal liner as a liner and the stacked FET device fabrication method further includes a fill operation following the conformal metal liner deposition in a space bounded by the conformal metal liner to insulate the metal liner.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the disclosure, in a stacked FET, an upper FET device is stacked on top of a lower FET device and typically the upper FET device and the lower FET device are vertically aligned. In some cases, however, a stacked FET can have an offset or staggered formation in which the upper FET device is offset or staggered from the lower FET device. In these instances, a vertical center of the upper FET device is not located above the bottom FET device. For those stacked FETs having such an offset or staggered formation, it can be difficult to connect respective gate metals of each of the upper FET device and the lower FET device.

Turning now to an overview of the aspects of the disclosure, one or more embodiments of the disclosure address the above-described shortcomings of the prior art by providing stacked FETs with a vertical metal spacer or liner forming a conductive gate merge connection. The vertical metal spacer or liner forms the conductive gate merge connection along a sidewall of the top device gate and to the bottom device gate and can be formed by gate cut processes and conformal metal deposition processes. The top or upper FET (i.e., the upper FET device) has a gate cut formation that can be formed by a deep gate cut process, which cuts a full gate height to a top of a self-aligned contact (SAC) cap of a bottom or lower FET (i.e., the lower FET device). The gate merge connection can be formed with conformal metal deposition along sidewalls of the upper FET device gate and down to the top of the SAC cap of the lower FET device. A metal plug can be formed within the SAC cap of the lower FET device to provide for electrical connection between the upper and lower FET devices via the vertical metal spacer/liner.

The gate merge connection can be formed by a post-replacement metal gate (post-RMG) gate cut, conformal metal deposition during which a liner configuration ends, followed by optional directional etch for spacer configurations and dielectric fill processing.

The above-described aspects of the disclosure address the shortcomings of the prior art by providing a stacked field effect transistor (FET) device including a lower FET, an upper FET disposed over the lower FET in a vertically mis-aligned formation, oxide vertically interposed between the lower FET and the upper FET and a gate merge connection. The lower FET includes lower gate metal surrounding semiconductor channels and an SAC cap disposed over the lower gate metal. The upper FET includes upper gate metal surrounding semiconductor channels. The gate merge connection includes a metal plug and a metal liner or a conformal metal liner. The metal plug is disposed in the SAC cap and in contact with the lower gate metal. The metal liner is disposed as a spacer along the upper gate metal and the oxide and in contact with the metal plug. The conformal metal liner is disposed as a liner along the upper gate metal, the oxide and the SAC cap and in contact with the metal plug.

In addition, the above-described aspects of the disclosure address the shortcomings of the prior art by also providing a stacked field effect transistor (FET) device fabrication method. The stacked FET fabrication method includes forming a lower FET comprising lower gate metal surrounding semiconductor channels and an SAC cap disposed over the lower gate metal, disposing a metal plug in the SAC cap and in contact with the lower gate metal and disposing oxide over the lower FET, the SAC cap and the metal plug. The stacked FET fabrication method further includes forming, over the oxide in a vertically misaligned formation with the lower FET, an upper FET comprising upper gate metal surrounding semiconductor channels, executing gate cut patterning to expose the SAC cap and the metal plug and forming a metal liner along the upper gate metal and the oxide and in contact with the metal plug.

With reference to FIG. 1, a stacked FET device 101 is provided and includes a substrate 110 forming a pillar 111 with shallow trench isolation (STI) 1112 between the pillar 111 and adjacent pillars, a lower FET 120 disposed on the pillar 111, an upper FET 130 disposed over the lower FET 120 in a vertically mis-aligned formation 102 (i.e., over the STI 1112), oxide 140 that is vertically interposed between the lower FET 120 and the upper FET 130 and a gate merge connection 150. The lower FET 120 includes lower gate metal 121 surrounding semiconductor channels (i.e., nanosheet channels) 122 and an SAC cap 123 that is disposed over the lower gate metal 121. The upper FET 130 includes upper gate metal 131 surrounding semiconductor channels (i.e., nanosheet channels) 132. The oxide 140 can include or be provided as bonding oxide.

The gate merge connection 150 includes a metal plug 160 and a metal liner 170. The metal plug 160 is disposed in the SAC cap 123 between first and second sides of the SAC cap 123 and in electrical contact with the lower gate metal 121. The metal liner 170 is disposed as a spacer along respective sidewalls of the upper gate metal 131 and the oxide 140 and in electrical contact with the metal plug 160. The metal plug 160 can be vertically aligned with the metal liner 170 and/or can be provided in edge-wise vertical alignment with an edge of the upper FET 130. The stacked FET device 101 can further include filler material 180, such as oxide or another suitable dielectric material, which is disposed on an uppermost surface of the SAC cap 123 and along a sidewall of the metal liner 170.

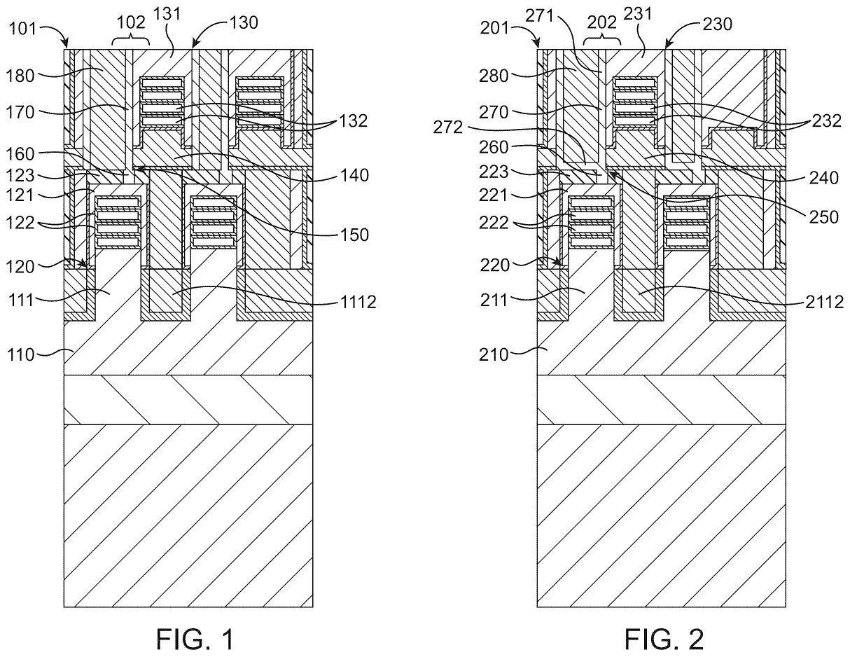

With reference to FIG. 2, a stacked FET device 201 is provided and includes a substrate 210 forming a pillar 211, a lower FET 220 disposed on the pillar 211 with STI 2112 between the pillar 211 and adjacent pillars, an upper FET 230 disposed over the lower FET 220 in a vertically mis-aligned formation 202 (i.e., over the STI 2112), oxide 240 that is vertically interposed between the lower FET 220 and the upper FET 230 and a gate merge connection 250. The lower FET 220 includes lower gate metal 221 surrounding semiconductor channels (i.e., nanosheet channels) 222 and an SAC cap 223 that is disposed over the lower gate metal 221. The upper FET 230 includes upper gate metal 231 surrounding semiconductor channels (i.e., nanosheet channels) 232. The oxide 240 can include or be provided as bonding oxide.

The gate merge connection 250 includes a metal plug 260 and a conformal metal liner 270. The metal plug 260 is disposed in the SAC cap 223 between first and second sides of the SAC cap 223 and in electrical contact with the lower gate metal 221. The conformal metal liner 270 is disposed as a liner along respective sidewalls of the upper gate metal 231, the oxide 240 and the SAC cap 223 and in electrical contact with the metal plug 260. The conformal metal liner 270 can include a vertical section 271 that is disposed along respective sidewalls of the upper gate metal 231 and the oxide 240 and a horizontal section 272 that is disposed along an uppermost surface of the SAC cap 223. The metal plug 260 can be vertically aligned with the vertical section 271 of the conformal metal liner 270 and/or can be provided in edge-wise vertical alignment with an edge of the upper FET 230. The stacked FET device 201 can further include filler material 280, such as oxide or another suitable dielectric material, which is disposed in a space bounded by the conformal metal liner 270.

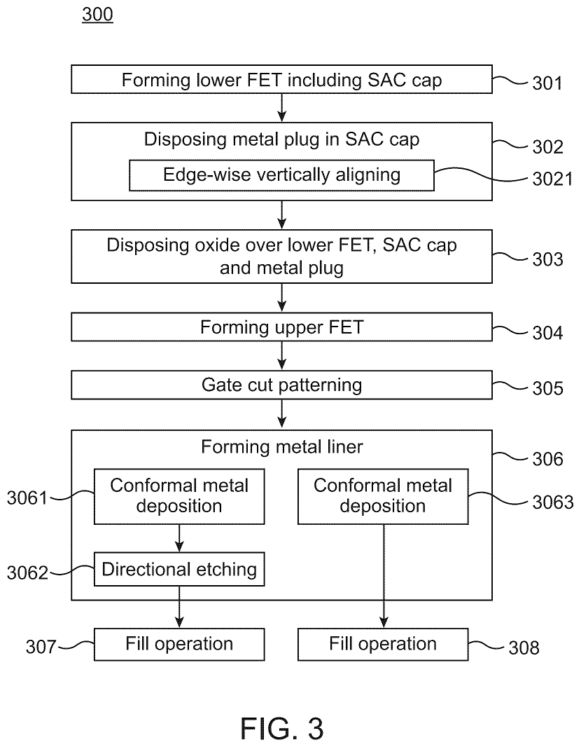

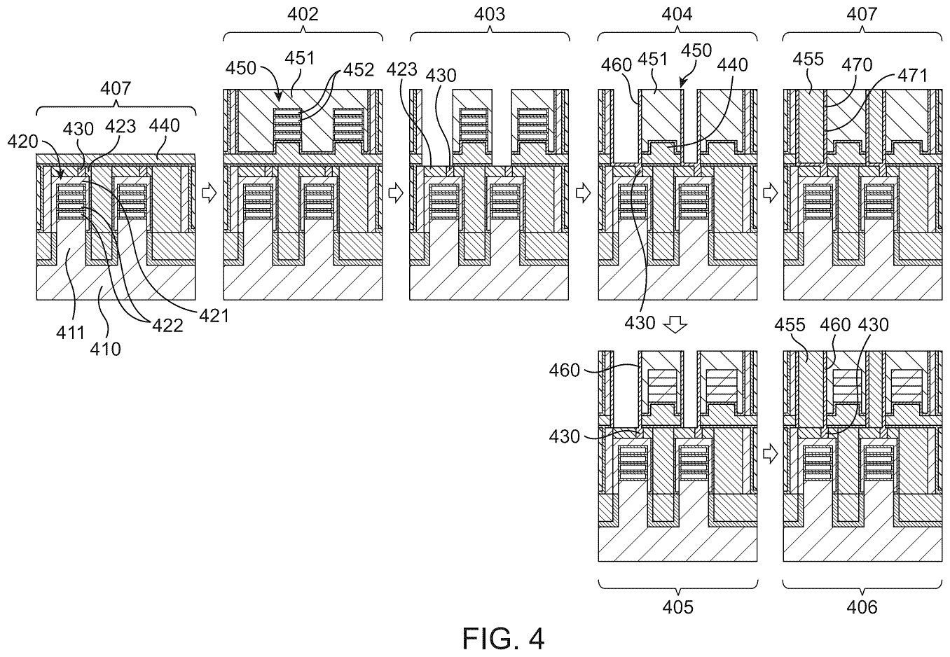

With continued reference to FIGS. 1 and 2 and with additional reference to FIG. 3, a stacked FET device fabrication method 300 is provided. As shown in FIG. 3, the stacked FET device fabrication method 300 includes forming a lower FET including lower gate metal surrounding semiconductor channels and an SAC cap disposed over the lower gate metal (block 301), disposing a metal plug in the SAC cap and in contact with the lower gate metal (block 302) and disposing oxide over the lower FET, the SAC cap and the metal plug (block 303). As shown in FIG. 3, the stacked FET fabrication method 300 further includes forming, over the oxide in a vertically misaligned formation with the lower FET, an upper FET including upper gate metal surrounding semiconductor channels (block 304), executing gate cut patterning to expose the SAC cap and the metal plug (block 305) and forming a metal liner along the upper gate metal and the oxide and in contact with the metal plug (block 306). The disposing of the metal plug of block 302 can include edge-wise vertically aligning the metal plug with an edge of the upper FET (block 3021).

In accordance with one or more embodiments of the present invention, the forming of the metal liner of block 306 can include conformal metal deposition (block 3061) immediately following the gate cut patterning of block 305 and directional etching (block 3062) to expose the SAC cap and to form the metal liner as a spacer. In these or other cases, the stacked FET device fabrication method 300 can further include a fill operation (block 307) immediately following the directional etching of block 3062 on an uppermost surface of the SAC cap and along a sidewall of the metal liner.

In accordance with one or more embodiments of the present invention, the forming of the metal liner of block 306 can include conformal metal liner deposition (block 3063) immediately following the gate cut patterning of block 305 to form a conformal metal liner as a liner. In these or other cases, the stacked FET device fabrication method 300 can further include a fill operation (block 308) immediately following the conformal metal liner deposition of block 3063 in a space bounded by the conformal metal liner.

With reference to FIG. 4, the stacked FET device fabrication method 300 of FIG. 3 is illustrated in graphical form.

As shown in image 401 of FIG. 4, the stacked FET device fabrication method 300 of FIG. 3 initially includes forming, on the pillar 411 of substrate 410 with STI 4101 between the pillar 411 and adjacent pillars, the lower FET 420 including the lower gate metal 421 surrounding the semiconductor channels 422 and the SAC cap 423 disposed over the lower gate metal 421, disposing the metal plug 430 in the SAC cap 423 and in electrical contact with the lower gate metal 421 and disposing the oxide 440 over the lower FET 420, the SAC cap 423 and the metal plug 430.

As shown in image 402 of FIG. 4, the stacked FET fabrication method 300 of FIG. 3 further includes forming, over the oxide 440 in the vertically misaligned formation with the lower FET 420 (i.e., over the STI 4101), the upper FET 450 including upper gate metal 451 surrounding semiconductor channels 452.

As shown in image 403 of FIG. 4, the stacked FET fabrication method 300 of FIG. 3 next includes executing gate cut patterning to expose the SAC cap 423 and the metal plug 430.

As shown in images 404, 405, and 406 of FIG. 4, the stacked FET fabrication method 300 of FIG. 3 next includes forming the metal liner 460 as the spacer along the upper gate metal 451 and the oxide 440 and in contact with the metal plug 430 where the metal plug 430 is vertically aligned with the metal liner 460 and in edge-wise vertical alignment with the edge of the upper FET 450. That is, in accordance with one or more embodiments of the present invention, the metal liner 460 can be formed by conformal metal deposition (see image 404 of FIG. 4) immediately following the gate cut patterning and directional etching (see image 405 of FIG. 4) to expose the SAC cap 423 and to form the metal liner 460 as the spacer. In these or other cases, the stacked FET device fabrication method 300 can further include a fill operation (see image 406 of FIG. 4) with oxide 455 immediately following the directional etching on the uppermost surface of the SAC cap 423 and along the sidewall of the metal liner 460.

As shown in images 404 and 407 of FIG. 4, the stacked FET fabrication method 300 of FIG. 3 next includes forming the conformal metal liner 470 as the liner along the upper gate metal 451, the oxide 440 and the uppermost surface of the SAC cap 423 and in electrical contact with the metal plug 430 where the metal plug 430 is vertically aligned with the vertical section 471 of the conformal metal liner 470 and in edge-wise vertical alignment with an edge of the upper FET 450. That is, in accordance with one or more embodiments of the present invention, the conformal metal liner 470 can be formed by conformal metal liner deposition (see image 404 of FIG. 4) immediately following the gate cut patterning. In these or other cases, the stacked FET device fabrication method 300 can further include a fill operation (see image 407 of FIG. 4) with oxide 455 immediately following the conformal metal liner deposition in the space bounded by the conformal metal liner 470.

Various embodiments of the present disclosure are described herein with reference to the related drawings. Alternative embodiments can be devised without departing from the scope of this disclosure. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a {100} orientated crystalline surface can take on a {100} orientation. In some embodiments of the disclosure, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present disclosure will now be provided. Although specific fabrication operations used in implementing one or more embodiments of the present disclosure can be individually known, the described combination of operations and/or resulting structures of the present disclosure are unique. Thus, the unique combination of the operations described in connection with the fabrication of a semiconductor device according to the present disclosure utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present disclosure. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present disclosure have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A stacked field effect transistor (FET) device, comprising:
a lower FET, an upper FET disposed over the lower FET in a vertically mis-aligned formation, and oxide vertically interposed between the lower FET and the upper FET,
wherein the lower FET comprises lower gate metal surrounding semiconductor channels and a self-aligned contact (SAC) cap disposed over the lower gate metal, and wherein the upper FET comprises upper gate metal surrounding semiconductor channels; and
a gate merge connection comprising:
a metal plug disposed in the SAC cap and in contact with the lower gate metal; and
a metal liner disposed as a spacer along the upper gate metal and the oxide and in contact with the metal plug.

2. The stacked FET device according to claim 1, wherein the oxide comprises bonding oxide.

3. The stacked FET device according to claim 1, wherein the semiconductor channels are nanosheets.

4. The stacked FET device according to claim 1, wherein the metal liner is disposed along respective sidewalls of the upper gate metal and the oxide.

5. The stacked FET device according to claim 1, wherein the metal plug is disposed between first and second sides of the SAC cap.

6. The stacked FET device according to claim 1, wherein the metal plug is vertically aligned with the metal liner.

7. The stacked FET device according to claim 1, wherein the metal plug is edge-wise vertically aligned with an edge of the upper FET.

8. The stacked FET device according to claim 1, further comprising filler material disposed on an uppermost surface of the SAC cap and along a sidewall of the metal liner.

9. A stacked field effect transistor (FET) device, comprising:
a lower FET, an upper FET disposed over the lower FET in a vertically mis-aligned formation, and oxide vertically interposed between the lower FET and the upper FET,
wherein the lower FET comprises lower gate metal surrounding semiconductor channels and a self-aligned contact (SAC) cap disposed over the lower gate metal, and wherein the upper FET comprises upper gate metal surrounding semiconductor channels; and
a gate merge connection comprising:
a metal plug disposed in the SAC cap in contact with the lower gate metal; and
a conformal metal liner disposed as a liner along the upper gate metal, the oxide, and the SAC cap and in contact with the metal plug.

10. The stacked FET device according to claim 9, wherein the oxide comprises bonding oxide.

11. The stacked FET device according to claim 9, wherein the semiconductor channels are nanosheets.

12. The stacked FET device according to claim 9, wherein the conformal metal liner is disposed along respective sidewalls of the upper gate metal and the oxide and is disposed along an uppermost surface of the SAC cap.

13. The stacked FET device according to claim 9, wherein the metal plug is disposed between first and second sides of the SAC cap.

14. The stacked FET device according to claim 9, wherein:
the conformal metal liner comprises a vertical section disposed along respective sidewalls of the upper gate metal and the oxide and a horizontal section disposed along an uppermost surface of the SAC cap, and
the metal plug is vertically aligned with the vertical section of the conformal metal liner.

15. The stacked FET device according to claim 9, wherein the metal plug is edge-wise vertically aligned with an edge of the upper FET.

16. The stacked FET device according to claim 9, further comprising filler material disposed in a space bounded by the conformal metal liner.

17. A stacked field effect transistor (FET) device fabrication method, comprising:
forming a lower FET comprising lower gate metal surrounding semiconductor channels and a self-aligned contact (SAC) cap disposed over the lower gate metal;
disposing a metal plug in the SAC cap and in contact with the lower gate metal;
disposing oxide over the lower FET, the SAC cap, and the metal plug;
forming, over the oxide in a vertically misaligned formation with the lower FET, an upper FET comprising upper gate metal surrounding semiconductor channels;
executing gate cut patterning to expose the SAC cap and the metal plug; and
forming a metal liner along the upper gate metal and the oxide and in contact with the metal plug.

18. The stacked FET device fabrication method according to claim 17, wherein the disposing of the metal plug comprises edge-wise vertically aligning the metal plug with an edge of the upper FET.

19. The stacked FET device fabrication method according to claim 17, wherein:
the forming of the metal liner comprises conformal metal deposition following the gate cut patterning and directional etching to expose the SAC cap and to form the metal liner as a spacer, and
the stacked FET device fabrication method further comprises a fill operation following the directional etching on an uppermost surface of the SAC cap and along a sidewall of the metal liner.

20. The stacked FET device fabrication method according to claim 17, wherein:
the forming of the metal liner comprises conformal metal liner deposition following the gate cut patterning to form a conformal metal liner as a liner, and
the stacked FET device fabrication method further comprises a fill operation following the conformal metal liner deposition in a space bounded by the conformal metal liner.
